(19) United States
(12) Patent Application Publication
(10) Pub. No.: US 2012/0172230 A1
(43) Pub. Date: Jul. 5, 2012

(54) Bi2223 OXIDE SUPERCONDUCTOR AND METHOD FOR PRODUCING SAME

(75) Inventors: Kazuaki Tatamidani, Osaka-shi (JP); Naoki Ayai, Osaka-shi (JP); Jun-ichi Shimoyama, Bunkyo-ku (JP)

(73) Assignee: SUMITOMO ELECTRIC INDUSTRIES, LTD., Osaka-shi, Osaka (JP)

(21) Appl. No.: 13/394,617

(22) PCT Filed: Aug. 5, 2010
(86) PCT No.: PCT/JP2010/063242

§ 371 Date: Mar. 7, 2012

(30) Foreign Application Priority Data
Sep. 8, 2009 (JP) 2009-207024

(51) Int. Cl. H01L 39/12; H01L 39/24; B29B 9/12; H01B 1/08

(52) U.S. Cl. 505/121; 505/100; 505/425; 264/5; 252/519.13

(57) ABSTRACT

The present invention provides a Bi2223 oxide superconductor composed of Bi, Pb, Sr, Ln, Ca, Cu, and O, wherein the Ln is at least one selected from La, Ce, Pr, Nd, Pm, Sm, Eu, Gd, Tb, Dy, Ho, Er, Tm, Yb, and Lu, and the composition ratio of Sr to Ln is a composition ratio described below. The Bi2223 oxide conductor has a high critical current density in a magnetic field at low temperature and is capable of maintaining a high critical current density in a self magnetic field even at 77 K. Sr:Ln=(1−x):x (wherein 0.002≦x≦0.015) Also, the present invention provides a method for producing the Bi2223 oxide superconductor, the method including a step of ionizing a material containing elements, which constitute the Bi2223 oxide superconductor, in a solution; and a step of removing a solvent and causing a thermal decomposition reaction by spraying the solution into a high-temperature atmosphere to produce a powder containing atoms constituting the oxide superconductor.

### TECHNICAL FIELD

The present invention relates to a Bi2223 oxide superconductor and a method for producing the same, and, in detail, relates to a Bi2223 oxide superconductor having a high critical current density in a magnetic field at low temperature and being capable of maintaining a high critical current density even in a self magnetic field at liquid nitrogen temperature (77 K), and a method for producing the same.

### BACKGROUND ART

In recent years, it has been reported that sintered oxide materials show a super conducting property with high critical temperature, and practical application of superconducting technology using these superconductors has been promoted. Among these oxide superconductors, Bi (bismuth)-based oxide superconductors are known as materials having a high critical current density, and among the Bi (bismuth)-based oxide superconductors, Bi2223 oxide superconductors composed of (Bi, Pb)₂—Sr₂—Ca₂—Cu₃ attract attention because wires having a high critical current density can be produced due to higher orientation.

However, the Bi2223 oxide superconductors have the problem of large depletion of the critical current density by application of a magnetic field parallel to the c-axis direction. For this problem, an attempt is made to improve the critical current density in a magnetic field by substitution with a Ln (lanthanide) element such as La.

Specifically, as disclosed in Patent Literature 1, a Bi2223 oxide superconductor produced by substituting a Bi-based oxide with 10% or more of a rare-earth element shows improved critical current density in a magnetic field. However, the Bi2223 oxide superconductor has the new problem of decreasing the critical current density in a self magnetic field at 77 K.

Also, Patent Literature 2 discloses a Bi-based oxide superconductor substituted with a Ln element. However, the Bi-based oxide superconductor involved in Patent Literature 2 is a Bi2212 oxide superconductor, and thus a sufficient critical current density cannot be obtained.

### CITATION LIST

### Patent Literature

Patent Literature 1: Patent Publication No. 2749194
Patent Literature 2: Japanese Unexamined Patent Application Publication No. 05-319827

### SUMMARY OF INVENTION

### Technical Problem

In consideration of the above-mentioned problems, an object of the present invention is to provide a Bi2223 oxide superconductor having a high critical current density in a magnetic field at low temperature and being capable of maintaining a high critical current density even in a self magnetic field at 77 K, and to provide a method for producing the same.

### Solution to Problem

The inventors conducted various researches on Bi2223 oxide superconductors substituted with Ln in order to resolve the above problems. As a result, the inventors found that conventional Bi2223 oxide superconductors substituted with Ln easily cause aggregation of a hetero phase because the amount of substitution is as large as 10% or more, and the critical current density in a self magnetic field at 77 K is decreased by the aggregation of a hetero phase.

Therefore, further research was conducted on a proper amount of Ln substitution, and as a result, it was found that with an amount of Ln substitution of 0.2 to 1.5%, it is possible to produce a Bi2223 oxide superconductor having a high critical current density in a magnetic field at low temperature and being capable of maintaining a high critical current density even in a self magnetic field at 77 K, leading to the completion of the present invention.

That is, a first aspect of the present invention relates to a Bi2223 oxide superconductor is composed of Bi, Pb, Sr, Ln, Ca, Cu, and O, wherein the Ln is at least one selected from La, Ce, Pr, Nd, Pm, Sm, Eu, Gd, Tb, Dy, Ho, Er, Tm, Yb, and Lu, and as the feature of this Bi2223 oxide superconductor, the composition ratio of Sr to Ln is the following composition ratio.

Sr:Ln=(1−x):x (wherein 0.002≦x≦0.015)

In the first aspect of the present invention, as described above, the aggregation of a hetero phase is suppressed because of a smaller amount of Ln substitution than a usual amount. As a result, it is possible to provide a Bi2223 oxide superconductor having a high critical current density in a magnetic field at low temperature and being capable of maintaining a high critical current density even in a self magnetic field at 77 K.

However, the Bi2223 oxide superconductor has a certain effect but cannot be completely prevented from aggregation of a hetero phase.

Accordingly, as a result of further intensive research, the inventors found that the aggregation of a hetero phase can be completely prevented by using a production method of a Ln-substituted Bi2223 oxide superconductor, including a step of ionizing a material containing elements, which constitute the Bi2223 oxide superconductor, in a solution, and a step of removing a solvent and causing a thermal decomposition reaction by spraying the solution into a high-temperature atmosphere to produce a powder containing atoms constituting the oxide superconductor, and thus a Bi2223 oxide superconductor having a high critical current density in a magnetic field at low temperature and being capable of maintaining a high critical current density even in a self magnetic field at 77 K can be provided.

That is, the materials containing elements which constitute the Bi2223 oxide superconductor are ionized in the solution, so that the elements in the solution can be finely mixed at the ionic level. In addition, the solution is sprayed into the high-temperature atmosphere to remove the solvent and cause a thermal decomposition reaction, so that the powder containing atoms constituting the oxide superconductor can be produced. Consequently, the elements can be homogeneously dispersed without segregation and aggregation, and thus Ln is allowed to be present in Bi2223 oxide crystal grains formed from a calcined powder. Since Ln present in the Bi2223 oxide crystal grains can function as pins in the Bi2223 oxide crystal grains, it is possible to achieve a high critical current density in a magnetic field at low temperature and maintain a high critical current density even in a self magnetic field at 77 K.

In a second aspect of the present invention, the above-described invention is claimed, a method for producing the Bi2223 oxide superconductor according to claim 1 includes a step of ionizing a material containing elements, which constitute the Bi2223 oxide superconductor, in a solution, and a step of removing a solvent and causing a thermal decomposition reaction by spraying the solution into a high-temperature atmosphere to produce a powder containing atoms which constitute the oxide superconductor.

### Advantageous Effects of Invention

According to the present invention, it is possible to provide a Bi2223 oxide superconductor having a high critical current density in a magnetic field at low temperature and being capable of maintaining a high critical current density even in a self magnetic field at 77 K, and to provide a method for producing the same.

### BRIEF DESCRIPTION OF DRAWINGS

FIG. 1 is a drawing schematically showing a configuration of an apparatus for producing a precursor powder of an oxide superconductor according to the present invention.

FIG. 2 is a graph showing critical current densities of Bi2223 oxide superconducting wires according to the present invention and standard composition wires in a self magnetic field and in a magnetic field at low temperature.

FIG. 3 is a graph showing a relation between the concentration of La added and a rate of increase in critical current density of a Bi2223 oxide superconducting wire according to the present invention.

FIG. 4A is an X-ray diffraction diagram of a precursor powder (La-added composition) of an oxide superconductor according to the present invention.

FIG. 4B is an X-ray diffraction diagram of a precursor powder (La not added) of an oxide superconductor with a standard composition.

### DESCRIPTION OF EMBODIMENTS

The present invention is described below on the basis of embodiments. The present invention is not limited to embodiments described below. The embodiments below can be variously changed within a scope which is the same as and equivalent to the present invention.

1. Method for Producing Precursor Powder

First, a method for producing a precursor powder is described.

(1) Preparation of Material

First, a material containing elements which constitute a Bi2223 oxide superconductor is prepared. That is, a material containing each of bismuth (Bi), lead (Pb), strontium (Sr), calcium (Ca), copper (Cu), and an element included in the lanthanides (Ln), such as lanthanum (La) which is substituted for part of Sr, and specifically, for example, material powders of Bi₂O₃, PbO, SrCO₃, CaCO₃, CuO, and La₂O₃ may be prepared. Alternatively, solid metals of Bi, Pb, Sr, Ca, Cu, and La may be prepared, or Bi(NO₃)₃, Pb(NO₃)₂, Sr(NO₃)₂, Ca(NO₃)₂, Cu(NO₃)₂, and La(NO₃)₃ or hydrates thereof may be prepared.

The above-described materials are weighed so that the ratio of (Bi, Pb):(Sr, Ln):Ca:Cu is 2:2:2:3.

(2) Preparation of Solution

Next, the prepared materials are dissolved to form a solution. As a solvent, nitric acid is preferred because the materials can be completely dissolved without forming passive states of the materials, and the carbon component can be made theoretically zero. However, the solvent is not limited to nitric acid, and another inorganic acid such as sulfuric acid, hydrochloric acid, or the like may be used, or an organic acid such as oxalic acid, acetic acid, or the like may be used. Further, not only an acid, but an alkaline solution may be used as long as it is a component which can dissolve the materials.

Then, the materials are ionized by being dissolved in, for example, nitric acid. The temperature of the solution is not particularly limited and may be any temperature at which material elements such as Bi etc. can be sufficiently dissolved. Further, in order to achieve sufficient solubility, stirring is preferably performed by providing a stirring apparatus.

In this way, the elements (Bi, Pb, Sr, Ca, Cu, and Ln) constituting an oxide superconductor are finely mixed at ionic level by completely dissolving the materials.

(3) Preparation of Precursor Powder

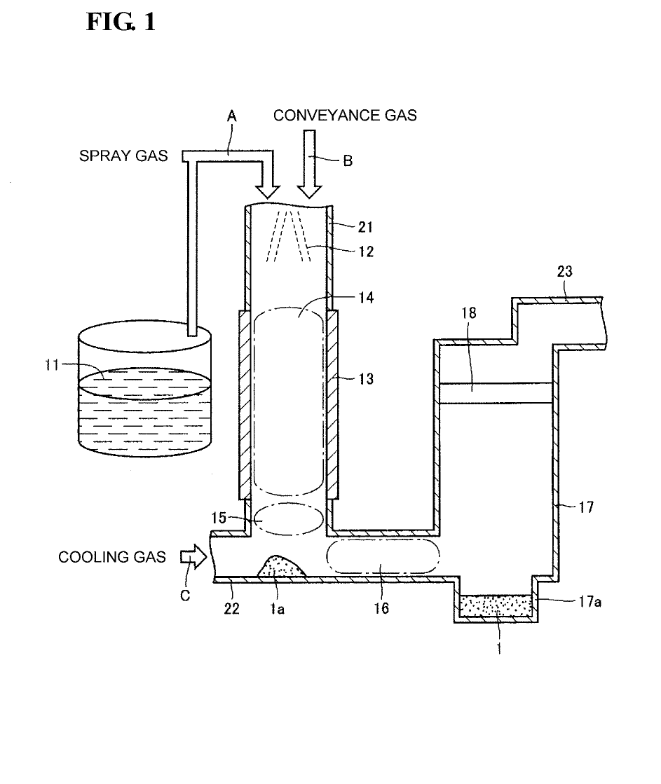

Next, a precursor powder is formed from the solution using a precursor powder producing apparatus shown in FIG. 1. Specifically, first, a solution 11 is sprayed, together with a gas for spray, from a spray nozzle 21. Spraying of the solution 11 and the spray gas is shown by arrow A. As a result, spray 12 is formed. On the other hand, a carrier gas is introduced from the spray nozzle 21 in a direction shown by arrow B. The spray 12 is conveyed to an electric furnace 13 with the carrier gas. In the electric furnace 13, the solvent taken from the solution 11 contained in the spray 12 is evaporated by heating.

Consequently, the solution is sprayed into a high-temperature atmosphere 14 including the spray gas and the carrier gas, to remove the solvent. This results in the production of a material powder 1a containing atoms which constitute the oxide superconductor. An atmosphere 15 at the outlet of the electric furnace 13 contains the component of the solvent removed.

The temperature of the electric furnace 13 is not particularly limited, but if nitrates are thermally decomposed in the electric furnace 13, the temperature of the electric furnace 13 can be adjusted at, for example, 700° C. or more and 850° C. or less. In addition, in the electric furnace 13, the length of a region at a temperature of 700° C. or more and 850° C. or less can be adjusted to, for example, 300 mm.

Then, the powder is cooled in an atmosphere 16 in which cooling gas is introduced. Specifically, the cooling gas is introduced in a direction shown by arrow C through a cooling gas inlet 22. The atmosphere 16 is formed by mixing the cooling gas with the atmosphere 15. The material powder 1a is transferred to a powder collector 17 with the carrier gas while being cooled in the atmosphere 16, and collected in a container 17a set at the bottom of the powder collector 17. As a result, a material powder 1 is produced. The carrier gas is passed through a filter 18 and then discharged from a discharge port 23.

In the embodiment of the present invention, dry air or nitrogen can be used as the spray gas. In addition, dry air can be used as the carrier gas. The spray gas and the carrier gas may be different gases or the same gas. The flow rate ratio between the spray gas and the carrier gas can be appropriately changed. Further, as the cooling gas, gas whose concentrations of carbon dioxide, nitrogen, and water vapor can be kept lower than those in the atmosphere 15 and whose temperature is lower than the atmosphere 15 is used.

(4) Calcination

Next, the powder is heat-treated. Specifically, the powder is oxidized by scattering in a high-temperature furnace to form precursor powder (calcined powder) of the Bi2223 oxide superconductor.

As the high-temperature furnace, a furnace which is capable of heating to a temperature required for completely thermally decomposing salts such as nitrates can be used. Specifically, the furnace can be used which can be heated up to the temperature from 600° C. to 850° C., for example, at which temperatures all nitrates contained in the powder are thermally decomposed, and which is equipped with a heat source provided on the periphery thereof. The inside of the high-temperature furnace is preferably maintained in an atmosphere where oxidation reaction easily takes place, for example, a low-oxygen atmosphere (e.g., an oxygen concentration of over 0% by volume and 21% by volume or less).

The inside of the high-temperature furnace is maintained at a temperature equal to or higher than the decomposition temperatures of nitrates, so that thermal decomposition reaction and oxidation reaction of the nitrates are quickly induced. In this way, the precursor powder composed of a composite oxide powder containing the elements at a predetermined ratio can be formed, in which each of the elements is homogenously dispersed without segregation and aggregation of an oxide of each element, particularly Ln oxide.

As described above, in producing the oxide superconductor, the elements of Bi, Pb, Sr, Ca, Cu, and Ln, which constitute the Bi2223 oxide superconductor, are finely mixed at the ionic level in the solution. Then, the solvent is removed from the solution to produce the powder in which each element is mixed at the ionic level. The produced powder is treated in the high-temperature furnace to quickly produce the precursor powder. Therefore, the precursor powder of the Bi2223 oxide superconductor can be produced, in which each of the elements is homogenously dispersed without segregation and aggregation of each element.

### Examples

The present invention is described in detail below on the basis of examples. In the examples, Bi2223 oxide superconducting wire was formed by using La as a Ln, an aqueous solution of nitrates of the elements, which constitute an oxide superconductor, as a material, and a precursor powder prepared by spraying and heat treatment after dissolving in acid solution.

1. Preparation of Precursor Powder

(1) Material

Five types of materials containing (Bi, Pb), (Sr₁₋ₓ, Laₓ), Ca, and Cu at a molar ratio of 2:2:2:3 and having different x values were prepared. Specifically, materials having x of 0.002, 0.005, 0.0075, 0.01, 0.01, and 0.015 were prepared and referred to as Example 1, Example 2, Example 3, Example 4, Example 5, and Example 6, respectively. Although Example 4 and Example 5 had the same composition ratio, both examples were distinguished from each other by a difference in the subsequent process for producing a superconducting wire.

(2) Dissolution and Removal of Solvent

Each of the six types of materials was dissolved in nitric acid to prepare an aqueous nitrate solution. Each of the six types of aqueous nitrate solutions was sprayed to form a powder.

(3) Calcination

Next, each of the powders was heat-treated in an atmosphere at a temperature of 800° C. and an oxygen partial pressure of 0.008 MPa for 10 hours to form a precursor powder.

2. Production of Bi2223 Oxide Superconducting Wire

(1) Formation of Monofilamentary Wire

A silver pipe was filled with each of the six types of the precursor powders and then heat-treated in vacuum atmosphere at 600° C. for 10 hours to remove gas. Brazing the ends of the metal pipe, the precursor powder was sealed in vacuum atmosphere, followed by wire drawing with both ends sealed, forming a monofilamentary wire.

(2) Formation of Tape Wire (Tape-Shaped MultiFilamentary Wire)

Next, 121 monofilamentary wires of each of the formed six types were inserted into a silver pipe and then again heat-treated in vacuum atmosphere at 600° C. for 10 hours to remove gas. Brazing the ends of the silver pipe, the precursor powder was sealed in vacuum atmosphere to form a multifilamentary wire. Then, the multifilamentary wire with both ends brazed was drawn and rolled to form a tape wire having a width of 4 mm and a thickness of 0.2 mm.

(3) Formation of Bi2223 Oxide Superconducting Wire

Next, each of the six types of tape wires was heat-treated at 820° C. to 830° C. and an oxygen partial pressure of 0.008 MPa for 30 hours. Next, each of the tape wires was intermediately rolled and further heat-treated in an atmosphere at 810° C. to 820° C. and an oxygen partial pressure of 0.008 MPa for 50 hours to produce a Bi2223 oxide superconducting wire.

3. Performance Test of Bi2223 Oxide Superconducting Wire

(1) Measurement Method

The critical current density (kA/cm²) of each of the produced Bi2223 oxide superconducting wires was measured under two types of conditions, i.e., in a self magnetic field at 77 K and in a magnetic field of 4 T applied perpendicularly to the tape (perpendicularly to the c-axis direction) at 20 K, and the measured values were denoted by Jc (77 K, s. f), i.e., the critical current density in the self magnetic field, and Jc (20 K, ⊥4 T), i.e., the critical current density in a magnetic field at low temperature, respectively. In addition, Jc (20 K, ⊥4 T)/Jc (77 K, s. f) was calculated as an up rate on the basis of the measured values.

(2) Measurement Results

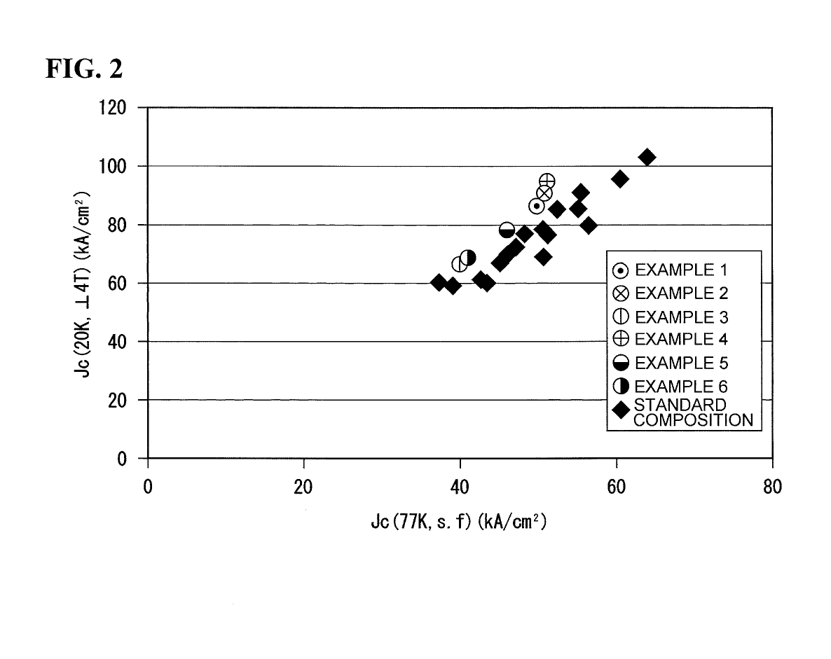

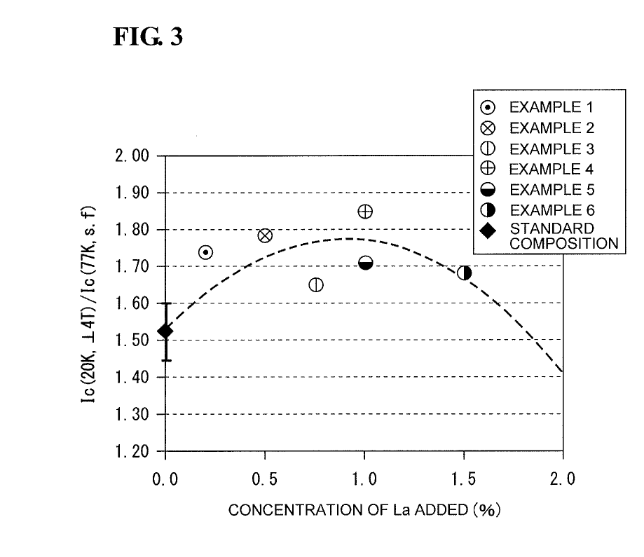

The measurement results are shown in Table 1, FIG. 2, and FIG. 3. In addition, measurement data of several types of Bi2223 standard composition wires, in which La was not added, i.e., x=0, is also shown in Table 1, FIG. 2, and FIG. 3. FIG. 3 is expressed in terms of critical current Ic.

TABLE 1

| | | Addition | | | |
|---|---|---|---|---|---|
| | | concentration | Jc(77 K, s. f) | Jc(20 K, ⊥4T) | Up rate |
| | Composition | (%) | (kA/cm2) | (kA/cm2) | (times) |
| Example 1 | (Bi,Pb)₂(Sr₁₋ₓ,Laₓ)₂Ca₂Cu₃O_{y} | 0.2 | 50 | 87 | 1.74 |
| Example 2 | (Bi,Pb)₂(Sr₁₋ₓ,Laₓ)₂Ca₂Cu₃O_{y} | 0.5 | 51 | 91 | 1.79 |
| Example 3 | (Bi,Pb)₂(Sr₁₋ₓ,Laₓ)₂Ca₂Cu₃O_{y} | 0.75 | 40 | 66 | 1.65 |
| Example 4 | (Bi,Pb)₂(Sr₁₋ₓ,Laₓ)₂Ca₂Cu₃O_{y} | 1.0 | 51 | 95 | 1.85 |
| Example 5 | (Bi,Pb)₂(Sr₁₋ₓ,Laₓ)₂Ca₂Cu₃O_{y} | 1.0 | 46 | 79 | 1.71 |
| Example 6 | (Bi,Pb)₂(Sr₁₋ₓ,Laₓ)₂Ca₂Cu₃O_{y} | 1.5 | 41 | 69 | 1.68 |
| Standard | (Bi,Pb)₂Sr₂Ca₂Cu₃O_{y} | 0 | 38-64 | 59-104 | 1.45-1.64 |
| Composition | | | | | |
| Wire | | | | | |

Table 1, and FIG. 3 indicate that a Bi2223 oxide superconducting wire produced according to the present invention has a high up rate, i.e., a high critical current density Jc (20 K, ⊥4 T) in a magnetic field at low temperature, as compared with the standard composition wire.

In the case of the Bi2223 oxide superconducting wire produced according to the present invention, it is considered that La added is homogeneously diffused at the ionic level, and thus La present in crystal grains of Bi2223 phase exhibits a pinning effect, so that the critical current density in a magnetic field at low temperature can be improved in spite of a low concentration of La.

Also, Table 1 and FIG. 2 indicate that a Bi2223 oxide superconducting wire produced according to the present invention has a critical current density Jc (77 K, s. f) in a self magnetic field equivalent to Jc (77 K, s. f) of a standard composition wire. That is, it is found that a decrease in critical current density in the self magnetic field due to La addition is suppressed.

In the case of the Bi2223 oxide superconducting wire produced according to the present invention, it is considered that La added is suppressed from aggregating between Bi2223 grains and forming a La hetero phase, thereby maintaining a high critical current density Jc (77 K, s. f) in the self magnetic field.

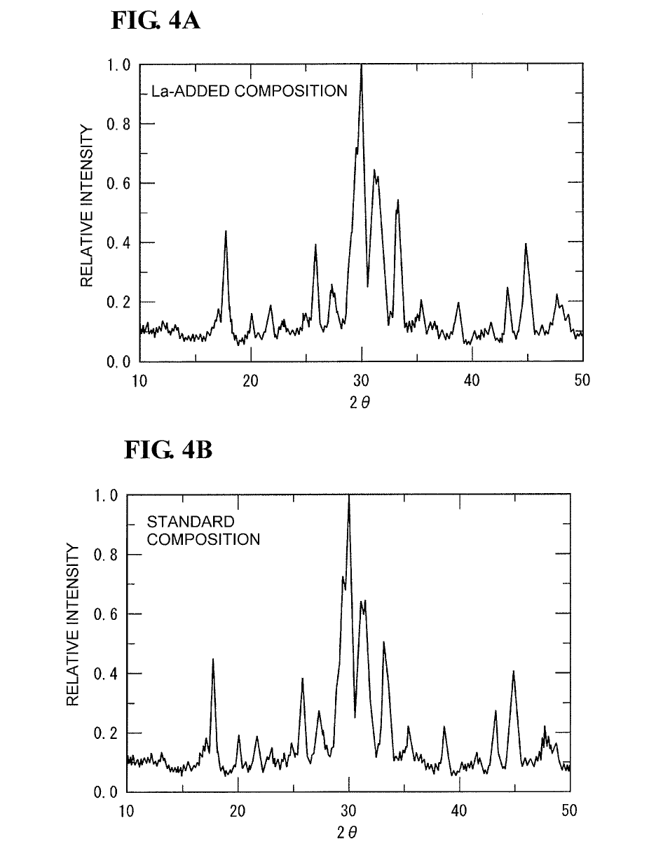

In order to confirm that a La hetero phase was not formed, X-ray diffraction measurement was performed for a precursor powder prepared according to the present invention and a precursor powder to which La was not added. The measurement results are shown in FIGS. 4A and 4B. In a diffraction diagram of the precursor powder prepared according to the present invention shown in FIG. 4A, diffraction peaks, diffraction angles, and diffraction intensities are substantially the same as in a diffraction diagram of the standard composition (La not added) shown in FIG. 4B, and a diffraction peak of a La hetero phase is not found in the diffraction diagram of the precursor powder prepared according to the present invention. Therefore, it was confirmed that the La hetero phase is not formed.

### INDUSTRIAL APPLICABILITY

A Bi2223 oxide superconductor of the present invention can be preferably used in the field of superconduction application in which a high critical current density is required even in a magnetic field at low temperature, and a high critical current density is required to be maintained even in a self magnetic field at 77 K. In addition, a method for producing a Bi2223 oxide superconductor of the present invention can be preferably used for producing a superconducting wire having the above-mentioned characteristics.

### REFERENCE SIGNS LIST

1, 1a material powder
11 solution
12 spray
13 electric furnace
14, 15, 16 atmosphere
17 powder collector
17a container
18 filter
21 spray nozzle
22 cooling gas inlet
23 discharge port

1. A Bi2223 oxide superconductor composed of Bi, Pb, Sr, Ln, Ca, Cu, and O,
wherein the Ln is at least one selected from La, Ce, Pr, Nd, Pm, Sm, Eu, Gd, Tb, Dy, Ho, Er, Tm, Yb, and Lu; and
the composition ratio of Sr to Ln is the following composition ratio.
Sr:Ln=(1−x):x (wherein 0.002≦x≦0.015)

2. A method for producing the Bi2223 oxide superconductor according to claim 1, the method comprising:
a step of ionizing a material containing elements, which constitute the Bi2223 oxide superconductor, in a solution; and
a step of removing a solvent and causing a thermal decomposition reaction by spraying the solution into a high-temperature atmosphere to produce a powder containing atoms constituting the oxide superconductor.
